(19) United States
(12) Patent Application Publication
(10) Pub. No.: US 2006/0267207 A1
(43) Pub. Date: Nov. 30, 2006

(54) Method of forming electrically conductive lines in an integrated circuit

(76) Inventors: Frank Feustel, Dresden (DE); Frank Koschinsky, Radebeul (DE); Peter Huebler, Coswig (DE)

Correspondence Address: WILLIAMS, MORGAN & AMERSON, 10333 RICHMOND, SUITE 1100, HOUSTON, TX, 77042, US

(21) Appl. No.: 11/347,053

(22) Filed: Feb. 3, 2006

(30) Foreign Application Priority Data
May 31, 2005 (DE) 10 2005 024 914.0

(51) Int. Cl. H01L 23/48; H01L 21/4763

(52) U.S. Cl. 257/774; 438/629; 257/E23.011

(57) ABSTRACT

In a method of forming a semiconductor structure, an opening is formed in a layer of a dielectric material provided over an electrically conductive feature. An etching process is performed in order to form a recess in the electrically conductive feature. The bottom of the recess may have a rounded shape. The recess and the opening are filled with an electrically conductive material. Due to the provision of the recess, electromigration, stress migration and a local heating of the semiconductor structure, which may adversely affect the functionality of the semiconductor structure, can be reduced.

### BACKGROUND OF THE INVENTION

1. Field of the Invention

The present invention relates to the formation of integrated circuits, and, more particularly, to the formation of electrically conductive lines provided in an integrated circuit.

2. Description of the Related Art

Integrated circuits comprise a large number of individual circuit elements such as, for example, transistors, capacitors and resistors, formed on and in a substrate. These elements are connected internally by means of electrically conductive lines to form complex circuits such as memory devices, logic devices and microprocessors. In order to accommodate all the electrically conductive lines required to connect the circuit elements in modern integrated circuits, the electrically conductive lines are arranged in a plurality of levels stacked on top of each other. In order to connect electrically conductive lines provided in different levels, contact vias are formed in dielectric layers separating the levels from each other. These vias are then filled with an electrically conductive material.

A method of forming an electrically conductive line according to the state of the art will now be described with reference to FIGS. 1a and 1b. FIG. 1a shows a schematic cross-sectional view of a semiconductor structure 100 in a first stage of the method of forming an electrically conductive line according to the state of the art. A semiconductor substrate 101 is provided. The semiconductor substrate 101 may comprise a plurality of circuit elements and, optionally, electrically conductive lines in lower interconnect levels. The semiconductor substrate 101 further comprises a first dielectric layer 102 formed thereon. In the layer 102, a trench 107 is formed. In the trench 107, a trench fill 111 comprising an electrically conductive material, for example a metal such as copper, is provided. The trench fill 111 forms an electrically conductive line. A diffusion barrier layer 110 separates the trench fill 111 from the first dielectric layer 102. Thus, a diffusion of the material of the trench fill 111 into the first dielectric layer 102 can be prevented and an adhesion between the trench fill 111 and the dielectric material of the first dielectric layer 102 can be improved. The semiconductor substrate 101 can be formed by means of methods known to persons skilled in the art comprising advanced techniques of deposition, oxidation, ion implantation, etching and photolithography.

An etch stop layer 103 is formed over the semiconductor substrate 101. In addition to the surface of the first dielectric layer 102, the etch stop layer 103 covers an exposed top surface of the trench fill 111. On the etch stop layer 103, a second dielectric layer 104 is formed. The second dielectric layer 104 may comprise the same material as the first dielectric layer 102. The etch stop layer 103 and the second dielectric layer 104 may be formed by means of methods known to persons skilled in the art, such as chemical vapor deposition, plasma enhanced chemical vapor deposition and spin coating.

A trench 109 and a contact via 108 are formed in the second dielectric layer 104. This can be done by photolithographically forming a mask (not shown) which exposes a portion of the surface of the second dielectric layer 104 at the location where the contact via 108 is to be formed. Then, an etching process is performed. To this end, the semiconductor structure 100 is exposed to an etchant adapted to selectively remove the material of the second dielectric layer 104, leaving the etch stop layer 103 essentially intact. Thus, the etching process stops as soon as the etch front reaches the etch stop layer 103.

The etching process may be anisotropic. In anisotropic etching, a rate at which material is removed from the etched surface depends on the orientation of the surface. The etch rate of substantially horizontal portions of the etched surface being substantially parallel to the surface of the semiconductor substrate 101 is significantly greater than the etch rate of inclined portions of the etched surface. Thus, substantially no material below the mask is removed and the via 108 obtains substantially vertical sidewalls. Thereafter, the mask is removed, which can be done by means of a resist strip process known to persons skilled in the art, and the trench 109 is formed. Similar to the formation of the contact via 108, the trench 109 can be formed by photolithographically forming a mask on the semiconductor structure 100 and performing an anisotropic etching process.

Subsequently, a portion of the etch stop layer 103 exposed at the bottom of the contact via 108 is removed. The exposed portion of the etch stop layer 103 can be removed by means of an etching process adapted to selectively remove the material of the etch stop layer 103, leaving the materials of the second dielectric layer 104 and the trench fill 111 substantially intact.

A diffusion barrier layer 105 is deposited on the semiconductor structure 100. In particular, the diffusion barrier layer 105 covers the sidewalls and the bottom of the trench 109 and the contact via 108. This can be done by means of known methods such as chemical vapor deposition, plasma enhanced chemical vapor deposition and/or sputter deposition. Then, a layer 106 of an electrically conductive material is formed on the diffusion barrier layer 105. To this end, methods of electroplating known to persons skilled in the art may be employed.

FIG. 1b shows a schematic cross-sectional view of the semiconductor structure 100 in a further stage of the method of forming an electrically conductive line according to the state of the art. The surface of the semiconductor structure 100 is planarized, for example by means of a known chemical mechanical polishing process. In the planarization process, portions of the diffusion barrier layer 105 and the layer 106 outside the trench 109 and the contact via 108 are removed and a planar surface of the semiconductor structure 100 is obtained. Residues of the layer 106 in the trench 109 form an electrically conductive line. Residues of the layer 106 in the contact via 108 provide an electrical contact between the electrically conductive lines in the trench 109 and the trench 107.

In the operation of the semiconductor structure 100, an electric current flowing between the electrically conductive lines in the trenches 107, 109 flows through a portion of the diffusion barrier layer 105 located at the bottom of the contact via 108. Typically, the material of the diffusion barrier layer 105, which may, for example, comprise tantalum or tantalum nitride, has a greater resistivity than the trench fill 111 and the material of the layer 106. Therefore, there is a voltage drop at the diffusion barrier layer 105.

A problem of the semiconductor structure 100 is that the electrical connection between the electrically conductive lines in the trenches 107, 109 provided by the contact via 108 is subject to failure caused by a formation of voids at the interface between the contact via 108 and the trench fill 111. Such voids may lead to an increase of the resistance of the electrical connection and, finally, to an opening of the connection. A failure of the electrical connection between electrically conductive lines may, in turn, adversely affect the operability of the semiconductor structure 100.

In view of the above problem, there is a need for a method of forming a semiconductor structure providing a more reliable electrical connection between electrically conductive features in different levels.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to an illustrative embodiment of the present invention, a method of forming a semiconductor structure comprises providing a semiconductor structure comprising a layer of dielectric material provided over an electrically conductive feature. An opening is formed in the layer of dielectric material. The opening is located over the electrically conductive feature. An etching process is performed to form a recess in the electrically conductive feature. The etching process is adapted to remove a material of the electrically conductive feature. The recess and the opening are filled with an electrically conductive material.

According to another illustrative embodiment of the present invention, a method of forming a semiconductor structure comprises providing a semiconductor substrate comprising a layer of dielectric material provided over an electrically conductive feature. An opening is formed in the layer of dielectric material. The opening is located over the electrically conductive feature. A recess is formed in the electrically conductive feature. The recess has a rounded shape and is located below the opening. The recess and the opening are filled with an electrically conductive material.

According to yet another illustrative embodiment of the present invention, a semiconductor structure comprises a semiconductor substrate. A dielectric layer is formed over the semiconductor substrate. The dielectric layer comprises an opening located over an electrically conductive feature provided in the semiconductor substrate. For any point of a bottom of the recess, a radius of a sphere conforming to the bottom at the point is greater than a minimum radius having a value in a range from about 15% of a diameter of the opening to about 20% of the diameter of the opening. The opening and the recess are filled with an electrically conductive material.

### BRIEF DESCRIPTION OF THE DRAWINGS

The invention may be understood by reference to the following description taken in conjunction with the accompanying drawings, in which like reference numerals identify like elements, and in which:

FIGS. 1a and 1b show schematic cross-sectional view of a semiconductor structure in stages of a method of forming an electrically conductive line according to the state of the art;

FIGS. 2a-2c show schematic cross-sectional views of a semiconductor structure in stages of a method of forming a semiconductor structure according to the present invention;

FIG. 3 shows a schematic cross-sectional view of a portion of a semiconductor structure in a stage of a method of forming a semiconductor structure according to the present invention; and

FIG. 4 shows a schematic cross-sectional view of a portion of a semiconductor structure in a stage of a method according to another embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the realization that the formation of voids at the interface between the contact via 108 and the trench fill 111 in the semiconductor structure 100 according to the state of the art is caused by effects of electromigration and stress migration which are enhanced by the structure of the interface between the contact via 108 and the trench fill 111.

The term “electromigration” denotes a current-induced transport of atoms in conductors. Electrons moving in an electrical field exchange momentum with the atoms. At high current densities, the momentum imparted to the atoms forms a net force which is high enough to propel atoms away from their sites in the crystal lattice. Thus, the atoms pile up in the direction of electron flow. The likelihood of electromigration is dependent, inter alia, on temperature, wherein moderately high temperatures increase the likelihood of electromigration occurring.

Moreover, an undesirable material transport in semiconductor structures may be caused by mechanical stress which can be created, e.g., due to different thermal expansion coefficients of an electrically conductive feature and a surrounding dielectric material. Such stress may relax via a diffusion of atoms in the electrically conductive feature. The diffusion of atoms entails a transport of material. This phenomenon is denoted as “stress migration.”

Due to the point effect, moderately high electrical fields are created at the edge of the bottom of the contact vias. These electrical fields entail high current densities in the vicinity of the edges. Due to the electrical resistivity of the materials of the contact via 108 and the trench fill 111, such high current densities can lead to a local heating of the contact via 108 and the trench fill 111 in the vicinity of the edge of the bottom of the contact via 108.

Both the occurrence of moderately strong electric fields and the occurrence of relatively high temperatures may increase the likelihood of electromigration occurring. Moreover, due to the local heating in the vicinity of the interface between the contact via 108 and the trench fill 111 on the one hand and the etch stop layer 103 and the second dielectric layer 104 on the other hand, mechanical stress may be created due to different thermal expansion coefficients of the materials of these features, which may lead to an occurrence of stress migration.

Electromigration and stress migration may lead to a transport of material away from the interface between the contact via 108 and the trench fill 111. Thus, voids which may lead to a failure of the electrical connection are formed.

The present invention generally relates to semiconductor structures and methods of forming a semiconductor structure wherein an interface between a contact via and a trench fill is adapted such that a likelihood of electromigration and stress migration occurring is reduced. To this end, a recess may be formed in an electrically conductive feature before filling an opening located above the electrically conductive feature with an electrically conductive material. Thus, the interface between the material in the opening and the material of the electrically conductive feature, where, in some embodiments of the present invention, a diffusion barrier layer similar to the diffusion barrier layer 105 can be formed, is provided at a distance to a layer of dielectric material surrounding the electrically conductive feature. Hence, mechanical stress caused by different thermal expansion coefficients may advantageously be reduced. Moreover, the recess may have a rounded shape. Hence, an occurrence of relatively strong local electric fields and moderately high current densities caused thereby can advantageously be reduced.

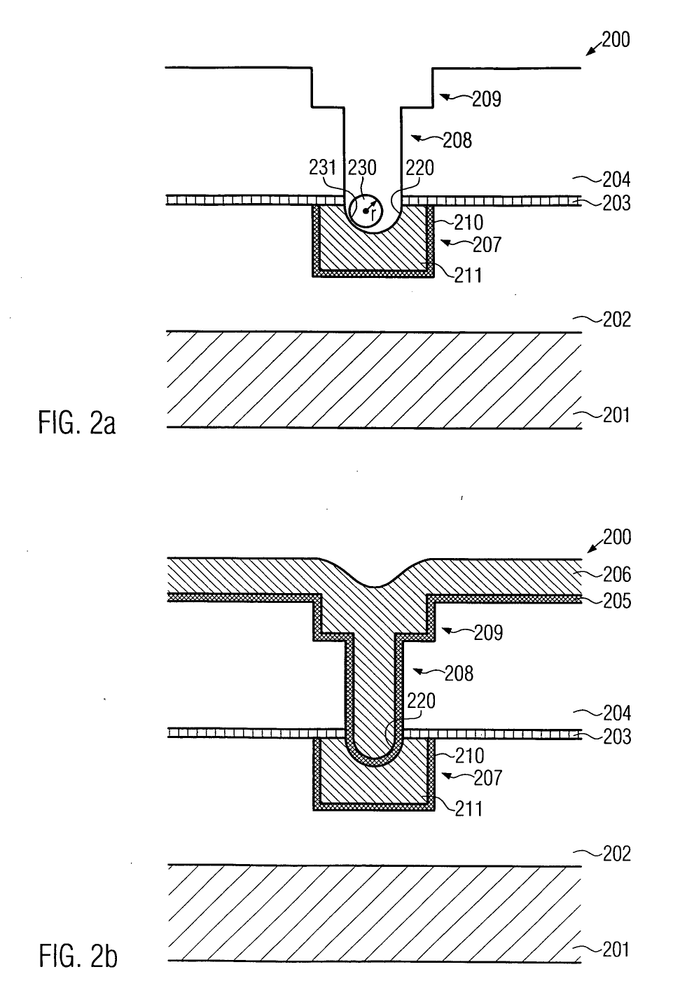

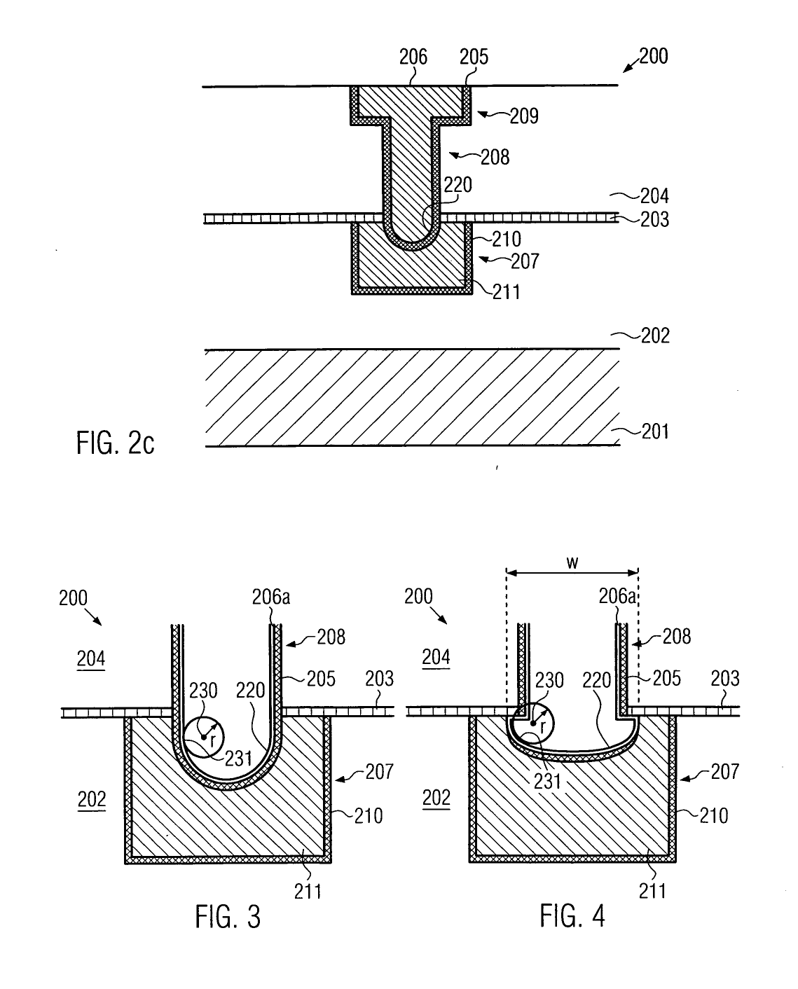

Further illustrative embodiments of the present invention will now be described with reference to FIGS. 2a-2c. FIG. 2a shows a schematic cross-sectional view of a semiconductor structure 200 in a first stage of a method of forming a semiconductor structure according to an embodiment of the present invention. The semiconductor structure 200 comprises a semiconductor substrate 201. The semiconductor substrate 201 may comprise circuit elements such a transistors, capacitors and resistors formed on a semiconductor wafer. Moreover, in some embodiments of the present invention, the semiconductor substrate 201 can comprise a plurality of electrically conductive lines in one or more lower interconnect levels.

The semiconductor substrate 201 further comprises a first dielectric layer 202 formed thereon. In the first dielectric layer 202, an electrically conductive feature provided in the form of a trench 207 filled with an electrically conductive trench fill 211 is formed. A diffusion barrier layer 210 separates the trench fill 211 from the first dielectric layer 210 and is adapted to increase an adhesion between the trench fill 211 and the first dielectric layer 202, as well as to substantially prevent a diffusion of the material of the trench fill 211 into the first dielectric layer 202.

The first dielectric layer 202 may comprise one of a variety of known dielectric materials, including silicon dioxide, silicon nitride, and low-k-materials such as silicon oxycarbide or hydrogen silsesquioxane. The trench fill 211 may comprise copper and the diffusion barrier layer 210 can comprise tantalum and/or tantalum nitride. In some embodiments of the present invention, the diffusion barrier layer 210 may comprise a plurality of sub-layers composed of different materials.

The semiconductor substrate 201 can be formed by means of methods known to persons skilled in the art comprising deposition, oxidation, ion implantation, etching and/or photolithography.

An etch stop layer 203 and a second dielectric layer 204 are deposited on the first dielectric layer 202. The second dielectric layer 204 may comprise the same material as the first dielectric layer 202. In other embodiments of the present invention, the first dielectric layer 202 and the second dielectric layer 204 can comprise different materials. The etch stop layer 203 may comprise SiN, SiC, or SiCN.

In the deposition of the etch stop layer 203 and the second dielectric layer 204, deposition methods known to persons skilled in the art such as chemical vapor deposition, plasma enhanced chemical vapor deposition and/or spin coating may be employed.

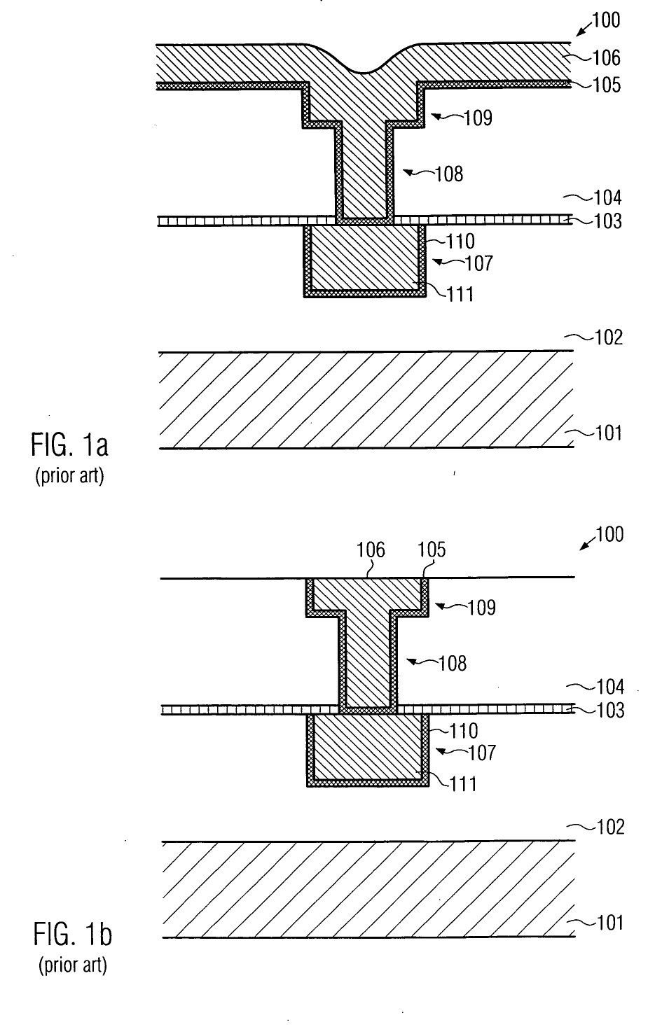

A contact via 208 and a trench 209 are formed in the second dielectric layer 204. Similar to the formation of the contact via 108 and the trench 109 in the method of forming an electrically conductive line according to the state of the art described above with reference to FIGS. 1a and 1b, the contact via 208 and the trench 209 may respectively be formed by photolithographically forming a mask (not shown) on the second dielectric layer 204 and then performing an anisotropic etching process. In the etching process, an etchant adapted to selectively remove the material of the second dielectric layer 204, leaving the material of the etch stop layer 203 substantially intact, is used. Thus, the etching process stops as soon as the etch stop layer 203 is exposed at the bottom of the contact via 208 and a contact between the etchant and the material of the trench fill 211 can substantially be avoided.

While, in some embodiments of the present invention, the contact via 208 is formed before the formation of the trench 209, in other embodiments of the present invention, the trench 209 may be formed first.

After the formation of the contact via 208 and the trench 209, the portion of the etch stop layer 203 exposed at the bottom of the contact via 208 is removed. This can be done by means of an etching process known to persons skilled in the art.

A recess 220 is formed in the trench fill 211. This can be done by means of an etching process adapted to selectively remove the material of the trench fill 211, leaving the dielectric material of the second dielectric layer 204 substantially intact. Alternatively, a non-selective etching process can be used. The etching process can be isotropic. In other embodiments of the present invention, an anisotropic etching process may be used.

In some embodiments of the present invention, the recess 220 may be formed by means of a dry etching process. In dry etching, a radio frequency glow discharge produces a chemically reactive species, such as atoms, radicals and ions, from a relatively inert molecular gas. The etching gas is selected such that the generated species reacts chemically with the material to be etched, creating a volatile reaction product. An energy of ions impinging on the semiconductor structure 200 may be controlled by varying a frequency applied in creating the glow discharge and/or applying a DC bias to the semiconductor structure 200. In general, the greater the energy of the ions, the more anisotropic or directional is the etching process.

In embodiments of the present invention wherein the trench fill 211 comprises copper, the dry etching process may be performed by means of an etching gas comprising a mixture of ammonia (NH₃) and water (H₂O). In other embodiments, the etching gas may comprise chlorine (Cl₂). A uniformity of the etching of copper may be improved by exposing the semiconductor structure 200 to a beam of ions prior to the etching process. Thus, copper at the surface of the trench fill 211 may be amorphized. This may help overcome problems resulting from a dependence of the etch rate of copper on grain orientation.

In further embodiments of the present invention, the recess 220 may be formed by means of a wet chemical etching process. In such embodiments, the etching process may be performed by inserting the semiconductor structure 200 into an aqueous solution of iron(III)-chloride (FeCl₃). Typically, wet etching processes are isotropic.

In still further embodiments of the present invention, the recess 220 can be formed by means of a sputter etching process. In sputter etching, ions of a sputtering gas, for example positively charged argon ions (Ar⁺), are created. This can be done by means of an electric discharge in the sputtering gas. The ions are accelerated towards the semiconductor structure 200. When the ions impinge on the semiconductor structure 200, atoms are ejected from the surface of the semiconductor structure 200. In particular, material at the surface of the trench fill 211 exposed at the bottom of the via 208 is removed by the bombardment with ions.

The recess 220 may have a rounded shape. A degree of rounding of the bottom surface of the recess 220 at a point 231 may be characterized by a radius “r” of a sphere 230 which conforms to the bottom surface at the point 231. The sphere 230 touches the bottom surface at the point 231. The center of the sphere 230 is located in the direction of normal to the bottom surface at the point 231. The radius “r” of the sphere 230 is adapted such that the curvature of the surface of the sphere is equal to the curvature of the bottom surface at the point 231, measured in the direction of greatest curvature. Hence, the radius “r” is equal to the absolute value of the main radius of curvature of the bottom surface at the point 231 having the greatest absolute value.

The sphere 230 is a mathematical object which is introduced in order to describe the curvature of the bottom of the recess 220 at the point 231. Alternatively, other methods of measuring the curvature may be employed. For example, an approximate sphere or an ellipsoid may be used in order to describe the curvature of the bottom of the recess at the point 231.

In some embodiments of the present invention, the radius of a sphere which conforms to the bottom surface at the respective point is greater than a predetermined minimum radius of curvature for any point of the bottom of the recess 220. The minimum radius of curvature determines the smoothness of the bottom of the recess 220. The greater the minimum radius of curvature, the smoother is the bottom of the recess.

The predetermined minimum radius of curvature may have a value in a range from about 15-30 μm. In other embodiments of the present invention, the minimum radius of curvature may be given as a fraction of the diameter of the contact via 208. For example, the minimum radius of curvature may have a value in a range from about 15% of the diameter of the via 208 to about 20% of the diameter of the via 208.

A schematic cross-sectional view of the semiconductor structure 200 in a later stage of the method of forming a semiconductor structure according to the present invention is shown in FIG. 2b. A more detailed cross-sectional view of a portion of the semiconductor structure 200 in an intermediate stage of the manufacturing process between the stage shown in FIG. 2a and the stage shown in FIG. 2b is shown in FIG. 3.

A diffusion barrier layer 205 is formed over the semiconductor structure 200. The diffusion barrier layer 205 covers the bottom surface of the recess 220, the side surface of the contact via 208, the bottom surface of the trench 209 and the sidewalls of the trench 209. Additionally, the diffusion barrier layer 205 may cover the horizontal top surface of the second dielectric layer 204. Similar to the formation of the diffusion barrier layer 105 in the method of forming an electrical connection described above with reference to FIGS. 1a and 1b, the diffusion barrier layer 205 can be formed by means of deposition techniques known to persons skilled in the art, such as chemical vapor deposition, plasma enhanced chemical vapor deposition and/or sputter deposition.

The recess 220, the contact via 208 and the trench 209 are filled with an electrically conductive material, for example a metal such as copper. The recess 220, the contact via 208 and the trench 209 may be filled by means of an electroplating process. To this end, a seed layer 206a (FIG. 3) comprised of the electrically conductive material can be formed on the diffusion barrier layer 205. In some embodiments of the present invention, the seed layer can be formed by means of a sputtering process wherein a target comprising the electrically conductive material is irradiated with ions. Due to the impact of ions on the target, atoms are ejected from the target. The ejected atoms may then be deposited on the surface of the semiconductor structure 200.

In other embodiments of the present invention, the seed layer 206 can be formed by means of an electroless deposition process. In electroless deposition, the semiconductor structure 200 is inserted into an aqueous plating solution. Solvents in the plating solution undergo a redox reaction with the material of the diffusion barrier layer 205. In the redox reaction, the electrically conductive material is formed. Further products of the redox reaction pass into a solved state in the plating solution and are thus removed from the semiconductor structure 200.

Advantageously, an electroless deposition of the seed layer allows a greater degree of isotropy of the deposition process. Thus, the seed layer may reliably be formed on steep portions of the semiconductor structure 200, such as, e.g., the sidewalls of the contact via 208 and the trench 209.

After the formation of the seed layer, the semiconductor structure 200 is inserted into a plating solution and an electric voltage is applied between the seed layer 206a and an electrode comprised of the electrically conductive material. A polarity of the electric voltage is such that, on average, the electrode becomes an anode and the semiconductor structure 200 becomes a cathode. Thus, at the electrode, atoms of the electrically conductive material are positively charged and change from the solid state in the electrode into a dissolved state in the plating solution. On the surface of the semiconductor structure 200, the ions are discharged and change from the dissolved state to the solid state. Thus, in the course of time, the layer 206 of the electrically conductive material is formed.

A schematic cross-sectional view of the semiconductor structure 200 in a later stage of the method of forming a semiconductor structure according to the present invention is shown in FIG. 2c. A planarization process is performed. The planarization process can comprise a chemical mechanical polishing process. In chemical mechanical polishing, the semiconductor structure 200 is moved relative to a polishing pad. A slurry comprising a chemical compound adapted to react with the material of the diffusion barrier layer 205 and the layer 206 of electrically conductive material is supplied to an interface between the semiconductor structure 200 and the polishing pad. The reaction products are removed by means of abrasives contained in the slurry and/or the polishing pad.

After the planarization, the semiconductor structure 200 comprises a substantially flat surface. The diffusion barrier layer 205 and the layer 206 of electrically conductive material are present only in the trench 209, the contact via 208 and the recess 220. The electrically conductive material in the trench 209 forms an electrically conductive line, whereas the electrically conductive material in the contact via 208 provides an electrical connection between the electrically conductive lines in the trenches 207, 209.

In the operation of the semiconductor structure 200, an electrical current flows between the electrically conductive lines in the trenches 207, 209 through the contact via 208 and the recess 220. Since the diffusion barrier layer 205 may have a greater resistivity than the electrically conductive material in the via 208, the recess 220 and the trench fill 211, there is a voltage drop at the portion of the diffusion barrier layer 205 provided at the bottom of the recess 220.

Due to the rounded shape of the bottom of the recess 220, a formation of strong local electric fields at the interface between the contact via 208 and the trench fill 211 may be significantly reduced compared to the electrical connection according to the state of the art described above with reference to FIGS. 1a and 1b. Correspondingly, an occurrence of large current densities can also be reduced. Hence, adverse effects resulting from electromigration, stress migration and/or a local heating of portions of the semiconductor structure 200 located in the vicinity of the interface between the contact via 208 and the trench 211 may substantially be avoided.

The bottom of the recess 220 need not be rounded, as shown in FIGS. 2a-2c and 3. In other embodiments of the present invention, the bottom of the recess 220 can have a relatively sharp edge similar to the bottom of the contact via 108 shown in FIG. 1b. Hence, the recess 220 has a substantially cylindrical shape. In such embodiments, the recess 220 may be formed by means of a highly anisotropic etching process. Relatively strong electric fields and, thus, relatively high current densities may occur at the edges of the recess. Since, however, the relatively high current densities occur inside the trench 207 filled with electrically conductive material, and electrically conductive materials such as copper have a high thermal conductivity, heat created due to the relatively high current densities may efficiently be dissipated. Hence, adverse effects of a local heating of the semiconductor structure 200 such as an occurrence of mechanical stress as well as an increased electromigration rate may be reduced.

A width of the recess 220 need not be identical to the width of the contact via 208, as shown in FIGS. 2a-2c and 3. In other embodiments of the present invention, the etching process applied in the formation of the recess 220 may be adapted to remove a portion of the trench fill 211 extending below a portion of the second dielectric layer 204 located adjacent the contact via 208. Thus, the recess 220 obtains a with “w” which is greater than the width of the contact via 208, as shown in FIG. 4. The removal of the portion of the trench fill 211 below the second dielectric layer 204 can be effected by providing an isotropic etching process in the formation of the recess 220.

Similar to the embodiment described above with reference to FIGS. 2a-2c and 3, after the formation of the recess 220, a diffusion barrier layer 205 is deposited. This can be done by means of chemical vapor deposition, plasma enhanced chemical vapor deposition and/or sputter deposition. In the deposition process, a material transport to the portions of the bottom of the recess 220 located below the second dielectric layer 204 can be reduced, since the second dielectric layer 204 may shadow these portions. Therefore, in the vicinity of the upper edge of the recess 220, a thickness of the diffusion barrier layer 205 may be smaller than in the rest of the bottom of the recess 220.

Subsequently, the recess 220, the contact via 208 and the trench 209 are filled with the electrically conductive material. This can be done by means of an electroplating process, as detailed above. It may be advantageous to deposit the seed layer by means of an electroless deposition process, since electroless deposition may allow more reliably covering of the portions of the bottom of the diffusion barrier layer exposed at the top of the recess 220 with the seed layer. Thus, an electrical contact between the portion of the seed layer 206a at the bottom of the recess 220 and the rest of the seed layer 206a may be improved.

When the contact via 208 and the recess 220 are filled with the electrically conductive material, due to the reduced thickness of portions of the diffusion barrier layer 205 in the vicinity of the upper edge of the recess 220, the electric resistance of these portions of the diffusion barrier layer 205 can be lower than that of the rest of the diffusion barrier layer 205. Thus, a current path having a low electrical resistance is created between the contact via 208 and the trench fill 211. This may help obtaining a high reliability of the electrical connection between the electrically conductive lines in the trenches 207, 209 can be obtained.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor structure, comprising:
providing a semiconductor substrate comprising a layer of a dielectric material provided over an electrically conductive feature;
forming an opening in said layer of dielectric material, said opening being located over said electrically conductive feature;
performing an etching process to form a recess in said electrically conductive feature, said etching process being adapted to remove a material of said electrically conductive feature; and
filling said recess and said opening with an electrically conductive material.

2. The method of claim 1, wherein said opening comprises a contact via.

3. The method of claim 1, wherein a bottom of said recess has a rounded shape.

4. The method of claim 3, wherein, for any point of said bottom of said recess, a radius of a sphere conforming to the bottom at said point is greater than a minimum radius having a value in a range from about 15% of a diameter of said opening to about 20% of the diameter of said opening.

5. The method of claim 3, wherein, for any point of said bottom of said recess, a radius of a sphere conforming to the bottom at said point is greater than a minimum radius having a value in a range from about 15-30 nm.

6. The method of claim 1, wherein said etching process is adapted to remove a portion of said electrically conductive feature extending below a portion of said layer of dielectric material located adjacent said opening.

7. The method of claim 6, wherein said etching process is an isotropic etching process.

8. The method of claim 1, wherein a diffusion barrier layer is formed prior to said filling of said recess and said opening with the electrically conductive material.

9. The method of claim 8, wherein said filling of said recess and said opening with the electrically conductive material comprises electroless deposition of a seed layer.

10. The method of claim 9, wherein said filling of said recess and said opening with the electrically conductive material further comprises an electroplating process.

11. A method of forming a semiconductor structure, comprising:
providing a semiconductor substrate comprising a layer of dielectric material provided over an electrically conductive feature;
forming an opening in said layer of dielectric material, said opening being located over said electrically conductive feature;
forming a recess in said electrically conductive feature, said recess having a rounded shape and being located below said opening; and
filling said recess and said opening with an electrically conductive material.

12. The method of claim 11, wherein said formation of said recess comprises performing an etching process adapted to remove a material of said electrically conductive feature, leaving said dielectric material substantially intact.

13. The method of claim 11, wherein said opening comprises a contact via.

14. The method of claim 11, wherein, for any point of a bottom of said recess, a radius of a sphere conforming to the bottom at said point is greater than a minimum radius having a value in a range from about 15% of a diameter of said opening to about 20% of the diameter of said opening.

15. The method of claim 11, wherein, for any point of a bottom of said recess, a radius of a sphere conforming to the bottom at said point is greater than a minimum radius having a value in a range from about 15-30 nm.

16. The method of claim 12, wherein said etching process is adapted to remove a portion of said electrically conductive feature extending below a portion of said layer of dielectric material located adjacent said opening.

17. The method of claim 16, wherein said etching process is an isotropic etching process.

18. The method of claim 11, wherein a diffusion barrier layer is formed prior to said filling of said recess and said opening.

19. The method of claim 18, wherein said filling of said recess and said opening with the electrically conductive material comprises electroless deposition of a seed layer.

20. The method of claim 19, wherein said filling of said recess and said opening with the electrically conductive material further comprises an electroplating process.

21. A semiconductor structure, comprising:
a semiconductor substrate;
a dielectric layer formed over said semiconductor substrate and comprising an opening located over an electrically conductive feature provided in said semiconductor substrate;
wherein, for any point of a bottom of said recess, a radius of a sphere conforming to the bottom at said point is greater than a minimum radius having a value in a range from about 15% of a diameter of said opening to about 20% of the diameter of said opening; and
wherein said opening and said recess are filled with an electrically conductive material.

22. The semiconductor structure of claim 21, further comprising a diffusion barrier layer formed on an inner surface of said opening and on said bottom of said recess.
